(19) United States
(12) Patent Application Publication
(10) Pub. No.: US 2014/0374146 A1
(43) Pub. Date: Dec. 25, 2014

(54) METAL NANONETWORK AND METHOD FOR PRODUCING THE SAME, AND CONDUCTIVE FILM AND CONDUCTIVE SUBSTRATE USING METAL NANONETWORK

(71) Applicant: FURUKAWA ELECTRIC CO.,LTD., Tokyo (JP)

(72) Inventors: Naoyuki SAITO, Tokyo (JP); Takuya HARADA, Tokyo (JP); Nobumitsu YAMANAKA, Tokyo (JP); Kazutomi MIYOSHI, Tokyo (JP); Michio OHKUBO, Tokyo (JP); Hiroshi IKEDA, Tokyo (JP)

(21) Appl. No.: 14/484,231

(22) Filed: Sep. 11, 2014

Related U.S. Application Data
(63) Continuation of application No. PCT/JP2013/055645, filed on Mar. 1, 2013.

(30) Foreign Application Priority Data
Mar. 15, 2012 (JP) 2012-058338

(51) Int. Cl. H05K 1/09; C30B 29/60; C30B 7/14; B22F 1/02; B22F 1/00

(52) U.S. Cl. CPC H05K 1/097; B22F 1/02; B22F 1/0044; B22F 1/0088; C30B 7/14; C30B 29/605; C30B 29/02
USPC 174/251; 148/527; 148/536; 428/593; 117/68

(57) ABSTRACT

A metal nanonetwork includes metal nanostructures that are joined by metallic bond. The joined part between the metal nanostructures includes a fillet part. In the joined part between the metal nanostructures, the distance between the central axis of one metal nanostructure and the central axis of another metal nanostructure is smaller than the sum of the radii of both metal nanostructures. The metal nanostructure is a metal nanowire. A first method for producing the metal nanonetwork includes a process of forming an oxide film on the outermost surface of the metal nanostructure, and a process of reducing the oxide film at the joined parts of a plurality of the metal nanostructures to thereby join the metal nanostructures.

### TECHNICAL FIELD

The present invention relates to a meshed metal nanonetwork etc., formed by joining metal nanostructures such as metal nanowires and metal nano dendrites.

### BACKGROND ART

Conventionally, metal nanowires with diameters in the nanometer level are produced by various methods (for example, see Patent Document 1).

Further, in Patent Document 2, a method for producing a transparent conductive film, wherein a coating liquid containing metal nanowire is applied onto a substrate to form a metal nanowire network layer, which is then pressurized by a roller to thereby enhance conductivity, is disclosed.

In Patent Document 3, a net-like structure obtained by joining metal nanowires through pressurizing or plating a network layer, in which metal nanowires lie on top of one another, is disclosed.

In Patent Document 4, a structure, wherein connection between the metal nanowires are strengthened by irradiating light etc. to a network layer in which conductive wire rods lie on top of one another, is disclosed.

In Patent Document 5, a metal nanowire structure obtained by plating metal into the grooves and pores of a net-like resin form, to form a metal net structure that is in accordance with the pattern, and removing the resin, is disclosed.

### RELATED ART DOCUMENT

### [Patent Documents]

[Patent Document 1] JP-A-2002-266007

[Patent Document 2] JP-A-2011-090878

[Patent Document 3] W02009/035059

[Patent Document 4] JP-A-2009-129607

[Patent Document 5] JP-A-2011-518674

### SUMMARY OF THE INVEVTION

### Problem to be Solved By The Invention

However, in the method of producing a metal nanonetwork by roller pressurization described in Patent Document 2, there were problems in that to enable the formation of the network layer, the configuration had to be planar, that deformation and kinks occurred in the metal nanowire due to pressing, and that the joining of metal nanowires was insufficient due to the surface oxide film. Further, because surface diffusion of metal atoms did not proceed due to the surface oxide film, there was a problem in that processing to form a fillet part was difficult, and that it was difficult to improve the joining strength of the nanowires by the fillet part.

In the method of producing a metal nanonetwork that utilizes plating, as described in Patent Document 3, there were problems in that the addition of metal salts were necessary to plate the metal nanowire that is applied onto the substrate, that the surface of the metal nanostructure became rough, and that the metal nanowires did not connect with one another tightly, because the central axis of the metal nanowires did not come in close proximity.

In the structure wherein connection between the metal nanowires is strengthened by the irradiation of light etc. described in Patent Document 4, there was a problem in that the joined area between the metal nanowires was small.

In the net-like metal nanowire structure obtained by utilizing a template, described in Patent Document 5, there was a problem in that the process of forming a fillet part in the resin template was difficult, and it was difficult to improve the joining strength of the metal nanowires by the fillet part. Note that because the metal is filled into the template by plating, the axial direction and crystal orientation of the metal nanowire forming the metal nanowire structure do not show a specific relationship.

As described above, in conventional metal nanowire networking means, the resistance at the connecting points were large, due to oxide films and dispersing agents intervening in the connection of the metal nanowires, and the joined areas between the metal nanowires being small, and the conductivity of the metal nanonetwork formed was unsatisfactory.

### Means for Solving the Problems

The present invention was made in view of the above-described problems, and its object is to obtain a metal nanonetwork, in which multiple metal nanostructures such as metal nanowires and metal nanodendrites are tightly connected by metallic bond, which shows high conductivity at the connecting points.

In order to achieve the above-described objects, the following invention is provided.
(1) A metal nanonetwork, which comprises metal nanostructures that are joined by metallic bond, wherein the joined part between the metal nanostructures comprise a fillet part, and in the joined part between the metal nanostructures, the distance between the central axis of one metal nanostructure and the central axis of another metal nano structure is smaller than the sum of the radii of the metal nanostructures, and the metal nanostructures are a metal nanowires.
(2) The metal nanonetwork of (1), wherein the crystal orientation in the axial direction of the metal nanowire is constant.
(3) The metal nanonetwork of (1), wherein a three-dimensional network is formed.
(4) The metal nanonetwork of (1), which comprises a trifurcated branching structure.
(5) The metal nanonetwork of (1), wherein an oxide does not intervene in the joined part between the metal nanostructures.
(6) The metal nanonetwork of (1), wherein the metal nanostructure comprises one metal selected from copper, silver, cadmium, iron, zinc, nickel and cobalt, as a main metal element that forms the metal nanostructure.
(7) The metal nanonetwork of (1), wherein the metal nanostructure is a single-crystal copper nanowire or a multiply-twinned copper nanowire.
(8) The metal nanonetwork of (1), which comprises a metal element that is more noble than the metal element composing the metal nanostructure, in the joined part between the metal nanostructures.
(9) The metal nanonetwork of (8), which comprises one metal element selected from copper, silver, cadmium, iron, zinc, nickel and cobalt as a main metal element composing the metal nanostructure, and the metal element that is more noble than the metal element composing the metal nanostructure is at least one metal element selected from gold, silver, platinum, palladium, rhodium, iridium, and ruthenium.
(10) The metal nanonetwork of (8), wherein the metal nanostructure is a single-crystal copper nanowire and the joined part between the metal nanostructures is composed of gold or an alloy of gold and copper.
(11) A method for producing a metal nanonetwork, which comprises a process of forming an oxide film on the outer-most surface of a metal nanostructure, and a process of reducing the oxide film in the joined parts of a plurality of metal nanostructures to thereby join the metal nanostructures.
(12) The method for producing a metal nanonetwork of (11), wherein the reducing of the oxide film is performed in a liquid containing a reducing agent.
(13) The method for producing a metal nanonetwork of (12), wherein the reducing agent is one of or a mixture of metal borohydride compounds, reducing sugars, hydrazine compounds, and polyols.
(14) The method for producing a metal nanonetwork of (11), wherein the metal nanostructure is a copper nanowire or a copper nanodendrite.
(15) A method for producing a metal nanonetwork, wherein: to a solution containing an ion or a complex of at least one metal element selected from copper, silver, cadmium, iron, zinc, nickel, and cobalt, as a main metal element that composes the metal nanostructure, a noble metal particulate, which contains a metal element more noble than the metal element in the solution, is added; and further, a capping agent, which selectively adsorbs to a specific surface of the metal element crystal to thereby grow the crystal in a specific direction, and a reducing agent are added.
(16) A method for producing a metal nanonetwork, wherein: to a solution containing an ion or a complex of at least one metal element selected from copper, silver, cadmium, iron, zinc, nickel, and cobalt as a main metal element that composes the metal nanostructure, a capping agent, which selectively adsorbs to a specific surface of the metal element crystal to thereby grow the crystal in a specific direction, and a reducing agent are added, to thereby form a metal nanowire; and during the metal nanowire formation reaction, a noble metal particulate that contains a metal element more noble than the metal element in the solution is added, to thereby join the metal nanowires to form a metal nanonetwork.
(17) The method for producing a metal nanonetwork of (15) or (16), wherein the noble metal particulate contains at least one metal element selected from gold, silver, platinum, palladium, rhodium, iridium, and ruthenium.
(18) The method for producing a metal nanonetwork of (15) or (16), wherein the metal element is copper and the metal element that is more noble is gold.
(19) The method for producing a metal nanonetwork of (15) or (16), wherein the capping agent is ammonia or an amine.
(20) The method for producing a metal nanonetwork of (15) or (16), wherein the reducing agent is hydrazine or a derivative thereof.
(21) A conductive film, which comprises the metal nanonetwork of any one of (1) to (11) embedded within a matrix resin.
(22) A conductive substrate, which comprises the conductive film of (21) formed on a substrate consisting of a resin, ceramic, or metal.

### ADVANTAGEOUS EFFECT OF THE INVENTION

From the present invention, a method for producing a metal nanonetwork, in which multiple metal nanostructures such as metal nanowires and metal nanodendrites are tightly connected by metallic bond, and shows high conductivity at the connecting points, as well as a metal nanonetwork, in which metal nanowires are tightly connected by metallic bond, and show high conductivity at the connecting points, can be obtained.

### BRIEF DESCRIPTION OF THE DRAWINGS

FIG. 1 is a drawing that shows the metal nanonetwork 1 of the present embodiment.

FIG. 2 is a drawing that exemplifies the metal nanodendrite 11.

FIG. 3(a), (b) are drawings that describe the first method for producing the metal nanonetwork.

FIG. 4(a), (b) are drawings that describe the formation process of the joined part in the first method for producing the metal nanonetwork.

FIG. 5(a), (b) are magnified drawings that describe the formation process of the joined part in the first method for producing the metal nanonetwork.

FIG. 6(a), (b) are drawings that describe the formation process of the trifurcated branching structure in the first method for producing the metal nanonetwork.

FIG. 7 (a), (b) are drawings that describe the second method for producing the metal nanonetwork.

FIG. 8 (a) to (c) are drawings that describe the formation process of the joined part in the second method for producing the metal nanonetwork.

FIG. 9 (a) to (c) are drawings that describe the third method for producing the metal nanonetwork.

FIG. 10 (a) to (c) are drawings that describe the formation process of the joined part in the third method for producing the metal nanonetwork.

FIG. 11 is a cross-sectional view of the conductive substrate 51 of the present embodiment.

FIG. 12 is a drawing that indicates the relationship between the mixing ratio and the electric conductivity, when the copper nanonetwork or the copper nanowire of the present embodiment is mixed into a resin as conductive fillers.

FIG. 13 is a scanning electron micrograph of the copper nanowire of Example 1.

FIG. 14 is a scanning electron micrograph of the copper nanonetwork of Example 1.

FIG. 15 is a scanning electron micrograph of the copper nanonetwork of Example 1.

FIG. 16 is a scanning electron micrograph of the copper nanonetwork of Example 1.

FIG. 17 is a scanning electron micrograph of the copper nanonetwork of Example 1.

FIG. 18 is a scanning electron micrograph of the copper nanonetwork of Example 2.

### DESCRIPTION OF PREFFERD EMBODIEMENTS OF THE INVENTION

### (Composition of the Metal Nanonetwork 1)

Hereinafter, embodiments of the present invention will be described in detail with reference to the accompanying figures.

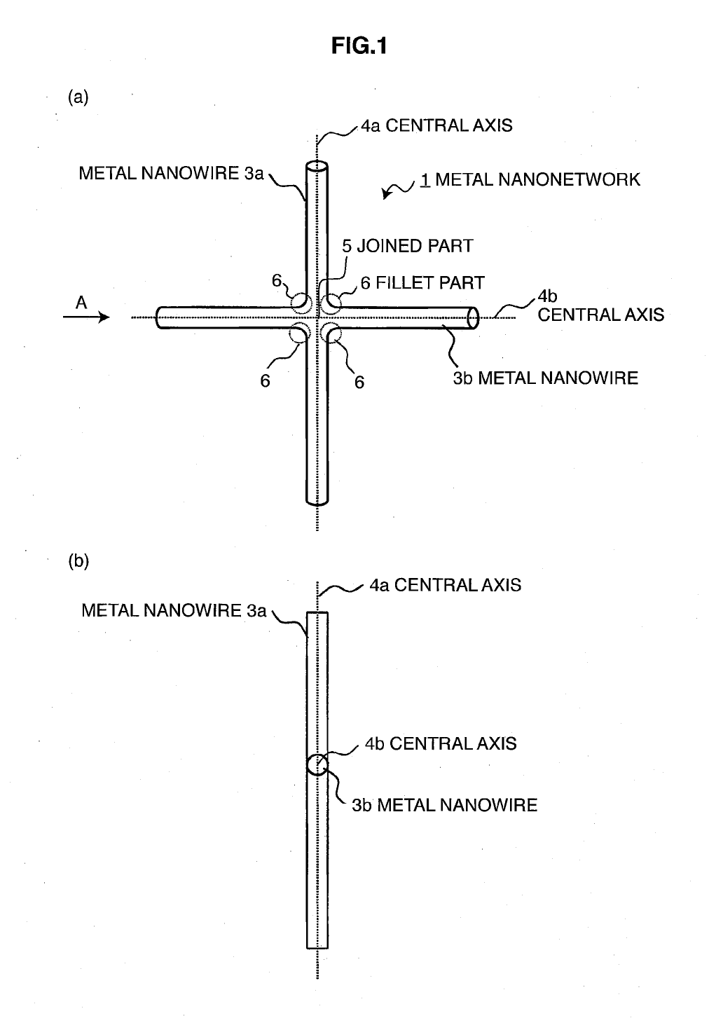

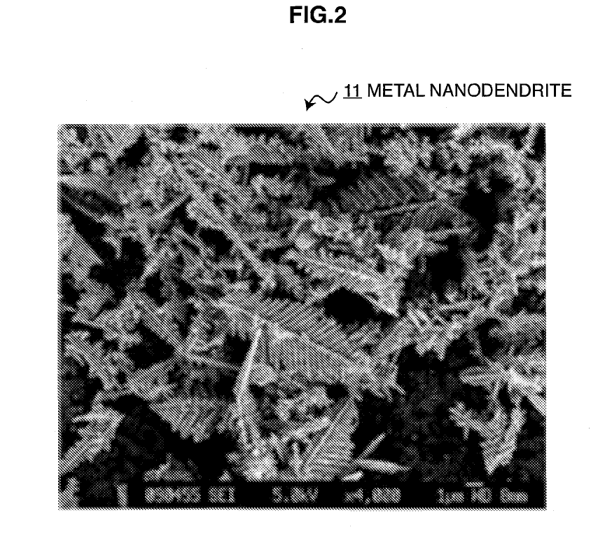

FIG. 1 is a drawing that shows the metal nanonetwork 1. The metal nanonetwork 1 is composed of a plurality of metal nanostructures that are joined by metallic bond at the joined part 5. In FIG. 1, metal nanowires 3a, 3b are used as the metal nanostructures, and metal nanowire 3a, 3b are joined at joined part 5 to form the metal nanonetwork 1. The metal nanonetwork 1 includes the metal nanonetwork 17 produced by the first production method, the metal nanonetwork 28 produced by the second production method, and the metal nanonetwork 35 produced by the third production method. Here, in order to at least form a network, it is preferable that the aspect ratio (length of the long axis/length of the short axis) of the metal nanostructure composing the metal nanonetwork 1 is 2 or more.

The metal nanonetwork 1 has a structure with a plurality of metal nanostructures connected together by metallic bond. Between one metal nanostructure and another metal nanostructure, a pathway connected by yet another metal nanostructure exists. For example, a net-like structure, wherein multiple units of near-polygonal structures, each consisting of a plurality of metal nanowires connected at the joined parts by metallic bond, are integrated, can be listed as one example of such metal nanonetwork. In particular, it is preferable that the net-like structure of the metal nanonetwork is not a planar structure, but rather expands three-dimensionally to form a three-dimensional network. In a three-dimensional network, the network structure is less stressed compared to a planar net-like structure, and distortion etc. of the wire is less likely to occur.

### (Metal Nanowire)

In particular, as examples of the metal nanostructure composing the metal nanonetwork 1, metal nanowires and metal nanodendrites can be listed. A metal nanowire is a linear structure of metal, wherein the diameter of the cross-section perpendicular to the longitudinal direction is 1 μm or less, or more specifically, 100 nm or less, and may also be called a metal nanofiber, metal nanorod, or metal nanowisker. Here, in the metal nanonetwork that uses the metal nanowire, metal nanoparticles or aggregates of metal nanoparticles may be joined onto part of the surface of the metal nanowire as the metal nanostructure.

### (Metal Nanodendrite)

A metal nanodendrite is a structure that comprises dendritic branching, and the diameter of each branch is 1 μm or less, or more specifically, 100 nm or less. A metal nanodendrite is, for example, a fine metal tree produced by having a metal of high ionization tendency come in contact with a solution of a metal ion with low ionization tendency, or a dendritic crystal produced by applying voltage to a metal ion solution, and has a fractal hierarchic structure. The nanodendrite structure has a three-dimensional configuration, comprising a main trunk (primary structure), a branched stem stretching from the main branch (secondary structure), and a fine branch that stretches from between the branches (tertiary structure), hierarchically. As the metal nanodendrite, a powdered nanodendrite 11 obtained by inserting two electrodes into a metal ion solution, applying low voltage, and peeling the dendritic crystal generated on the electrode, can be used. By reducing the metal nanodendrites in a state of contact, the contacting parts of the metal nanodendrites are reduced and joined at the same time, and a metal nanonetwork using metal nanodendrites is formed. For example, by using such metal nanodendrite structure, a complex network structure with the primary structure and secondary structure, along with the tertiary structure added thereto, can be constructed.

Here, the metal nanonetwork that utilizes metal nanowire as the metal nanostructure and the metal nanonetwork that utilizes metal nanodendrites as the metal nanostructure have different fractal dimensions. For this reason, the two can be distinguished from the point of fractal structure, even though they both share the same characteristic in that a plurality of metal nanostructures are connected with one another by metallic bond in at least one connecting point.

Further, the metal nanonetwork that is formed using metal nanowires and the metal nanonetwork that is formed using metal nanodendrites also differ in terms of their structure. Thus, if one wishes to form stable connecting points, it is better to form the metal nanonetwork using metal nanowires, while it is better to form the metal nanonetwork using the metal nanodendrites, if one wishes to increase the surface area of the metal nanonetwork structure or increase the number of connecting points, and the two can be used depending on the use or purpose.

### (Type of Metals)

The metal nanostructure contains at least one metal element selected from copper, silver, cadmium, iron, zinc, nickel, and cobalt as the main metal element that forms the metal nanostructure. By reducing oxides or hydroxides of these metal elements in an aqueous solution, or by electrolytic deposition of these metal elements, a metal nanostructure consisting of such metal elements singly, or a metal nanostructure having such metal elements as the main metal element, can be obtained. Furthermore, by performing processing under suitable conditions to the metal nanostructure of such metal elements, the metal nanostructure can easily form oxide films and hydroxide films.

Here, “contain at least one metal element selected from copper, silver, cadmium, iron, zinc, nickel, and cobalt as the main metal element that forms the metal nanostructure” is not intended to eliminate the presence of elements other than the main metal element, but rather, implies that the metal elements of copper, silver, cadmium, iron, zinc, nickel and cobalt that was not selected as the main metal element may coexist. The acceptable range at which multiple metal elements that were not selected may coexist is in a range that does not largely affect the lattice constant and the crystal structure of the main metal element. For example, an alloy in the range that forms a solid solution with the main metal element can be exemplified.

Hereinafter, an example wherein the metal nanostructure that composes the metal nanonetwork is metal nanowire will be described. In the joined part 5 between metal nanowire 3a and metal nanowire 3b, no oxide or hydroxide exist between metal nanowire 3a and metal nanowire 3b. That is, in the later-described first production method, by reducing the oxide film or hydroxide film on the surface of the metal nanowire, the metal nanowires connect by metallic bond. Thus, at the joined part, the oxide film or hydroxide film does not remain between the metal nanowires. Further, in the later-described second production method, the metal nanonetwork is formed without undergoing the metal nanowire state by reducing the metal ion or metal complex, no oxide film or hydroxide film is formed between the metal nanowires at the joined part. Furthermore, in the later-described third production method, after a metal ion or metal complex is reduced to begin the metal nanowire formation reaction, the reduction reaction is accelerated under the presence of noble metal particulates to thereby form the metal nanonetwork. Thus, at the joined part, no oxide film or hydroxide film is formed between the metal nanowires.

### (Fillet Part)

Further, the joined part 5 between metal nanowire 3a and metal nanowire 3b comprises a fillet part 6. The fillet part 6 may also be called a fillet. The fillet part 6 is formed so as to smooth out the joined part 5 that is formed by the metal nanowires 3a and 3b. Because the joined part 5 comprises a fillet part 6, the thickness of the joined part 5 becomes thicker than the thickness of the metal nanowires 3a and 3b. By having the fillet part 6, the metal nanowires 3a and 3b are able to be joined in a wider area than the cross-sectional area of the metal nanowires 3a or 3b. For this reason, metal nanowires 3a and 3b are joined tightly, and the mechanical strength of the metal nanonetwork increases. Note that the dotted circle at the fillet part 6 in the figure merely shows the region of the fillet part 6, and no structure corresponding to the dotted circle actually exists. The same can be said for the other figures.

Further, as described later, when the metal nanostructure is formed so that elements other than the main metal element forming the metal nanostructure is included, by alloying the fillet part of the metal nanowire, the strength of the fillet part can further be enhanced.

(Distance between the Central Axes at the Joined Part of the Metal Nanostructures)
(When the distance between the central axes is smaller than the sum of the radii of both metal nanostructures)

Further, in at least part of the joined parts between the metal nanostructures composing the metal nanonetwork 1, the distance between the central axis of one metal nanostructure and the central axis of the other metal nanostructure is smaller than the sum of the radii of both metal nanostructures. That is, the metal nanonetwork is formed so that the metal nanostructures penetrate each other at the contact point. In FIG. 1(a), (b), the distance between the central axis 4a of metal nanowire 3a and the central axis 4b of metal nanowire 3b is smaller than the sum of the radii of the two metal nanostructures at the joined part 5 of metal nanowire 3a and metal nanowire 3b. Because the distance is smaller than the sum of the radii of both metal nanostructures, the metal nanostructures are joined in a large area, and the mechanical strength of the metal nanonetwork is enhanced. Note that the central axis refers to the axis that connects the centers of gravity of the cross-section perpendicular to the long axis.

(When the Distance Between the Central Axes is Larger than or Equal to the Sum of the Radii of Both Metal Nanostructures)

Further, at the early stages of joining, the distance between the central axis of the two metal nanostructures can be larger than or equal to the sum of the radii of both metal nanostructures. For example, the joined part of the metal nanonetwork may form by either one of the following mechanisms: a reduction reaction occurs while the surface of a metal nanowire is in contact with the surface of another metal nanowire; or two metal nanowires in a state of proximity are joined via metal particles that grow with a noble metal particulate acting as the core. In such cases, immediately after formation, the central axes of the two connected metal nanowires are apart in a distance equivalent to the sum of the radii of one metal nanowire and the other metal nanowire, or further, in the latter case, are slightly further apart in a distance equivalent to the size of the mediating metal particle that grows from the noble metal particulate acting as the core. However, in such cases, diffusion of the atoms on the surface occur in order to minimize the surface energy of the joined parts, and the atoms composing the joined parts transfer to decrease the distance between the central axes. Hence, the distance between the central axes of the metal nanowires become smaller than the sum of the radii of both metal nanowires. Here, the noble metal particulate may be a particulate of, for example, 2 to 10 nm.

As described later, because the metal nanonetwork 1 is formed under a reduction environment, the metal atom at the joined part is activated. For this reason, after the surface of the metal nanowires come in contact and join, the metal atoms at the joined part diffuse under a reduction environment, and the metal nanowires join deeply, so that the surface energy of the joined part decreases. That is, the metal atoms transfer so that the central axes of the metal nanowires almost coincide. The driving force for the transfer of the metal atoms on the surface largely increases by the structure being in the nano-order. However, since the activation of the surface of the metal atoms by reduction is added to this increased driving force, the transfer of the atoms at the joined part is largely accelerated.

Thus, in the joining structure of the metal nanonetwork 1 of the present embodiment, the maximum distance between the central axes of the metal nanowires is less than or equal to the sum of the radii of the two metal nanowires, but there are various states in the distance between the central axes of the metal nanowires. Hence, as the joining structure of the metal nanowire, various states of joining, from being joined with the periphery of the metal nanowires circumscribing to the central axes almost coinciding, are included.

On the other hand, in the formation of the joined parts by pressurization or plating, as described in Patent Documents 2 and 3, the metal nanowires never join as deep as having the central axes coincide.

### (Crystal Structure)

Further, the crystal orientation of the metal nanowires 3a and 3b in the axial direction is unidirectional. In the later-described first production method, because the crystal orientation in the axial direction of the metal nanowire prior to networking is unidirectional at the time of metal nanowire formation, the crystal orientation of each metal nanowire in the axial direction also becomes unidirectional after networking. Further, in the second and third production methods, because the metal nanonetwork is formed by reducing a metal ion in a liquid phase containing a capping agent, which strongly adsorbs onto a specific surface of the crystal grain and inhibits crystal growth in that direction, the crystal orientation in the axial direction of each metal nanowire composing the metal nanonetwork becomes unidirectional. On the other hand, in the method described in Patent Document 5, because metal is filled in a template by plating, the metal filled inside the template becomes polycrystalline. Thus, the metal nanowires that compose the metal nanowire structure obtained are polycrystalline, and the crystal orientation never becomes unidirectional.

In particular, it is preferable that metal nanowires 3a and 3b are each single crystal or multiple twinning. Note that the joined part of the metal nanowire 3a and metal nanowire 3b may contain a crystal grain boundary. A metal nanowire that is multiple twinning implies that the metal nanowire contains a plurality of the same crystal, and each crystal is bound with a certain plane acting as the plane of symmetry or a certain line acting as the axis of symmetry, to form one metal nanowire.

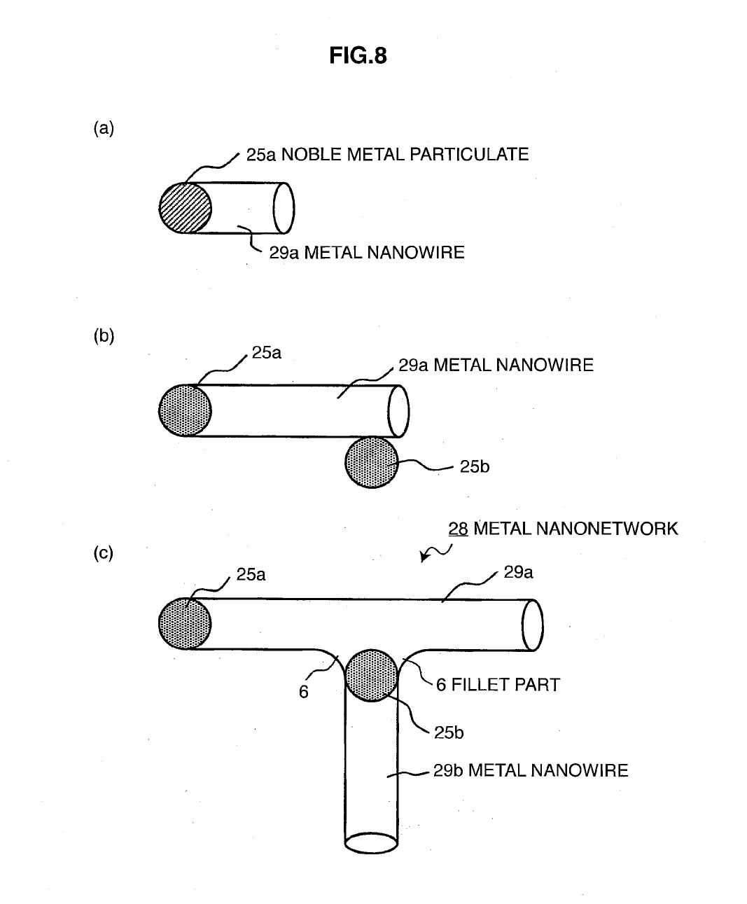

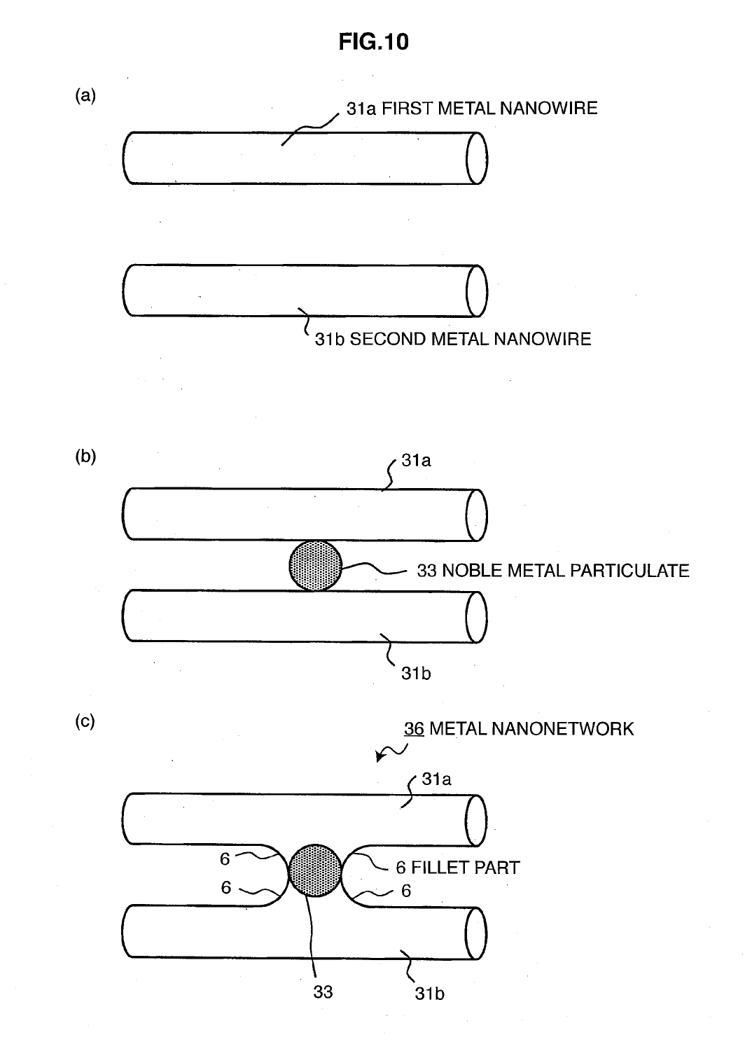

Further, as in the metal nanonetwork 28 shown in FIG. 8(c) and the metal nanonetwork 35 shown in FIG. 10(c), the joined parts between the metal nanostructures may contain a metal that is more noble than the metal composing the metal nano structure.

### (Inclusion of Noble Metal)

It is preferable that such metal nanostructure composing the metal nanonetwork contains at least one metal element selected from copper, silver, cadmium, iron, zinc, nickel, and cobalt as the main metal element. Further, as the metal element more noble than the aforementioned metal nanostructure, it is preferable that at least one metal element selected from gold, silver, platinum, palladium, rhodium, iridium, and ruthenium is included.

In particular, it is preferable that the metal nanostructure is copper nanowire, and the joined parts between the copper nanowires contain gold or an alloy of gold and copper.

### (First Method for Producing Metal Nanonetwork)

In the first method for producing the metal nanonetwork, the metal nanonetwork is produced by reducing the oxide film or hydroxide film on the surface of the metal nano structure to join the metal nano structures at the contact point. Note that in the metal nanostructures, the metal does not have to be all the same. Further, the type of metal nanostructure does not have to be either metal nanowire or metal nanodendrite alone, and may be a mixture thereof.

More specifically, first, the metal nanostructure is produced. The method by which the metal nanostructure is produced is not particularly limited, and may be, for example, a method of reducing metal ion, a method of synthesizing by chemical vapor deposition, etc. Hereinafter, as a representative of the metal nanostructure, metal nanowire will be used as an example.

A surface oxide film 7 is formed, at least on the outer-most surface of the metal nanowire, by exposure to atmosphere or by contact with an oxidizing solution.

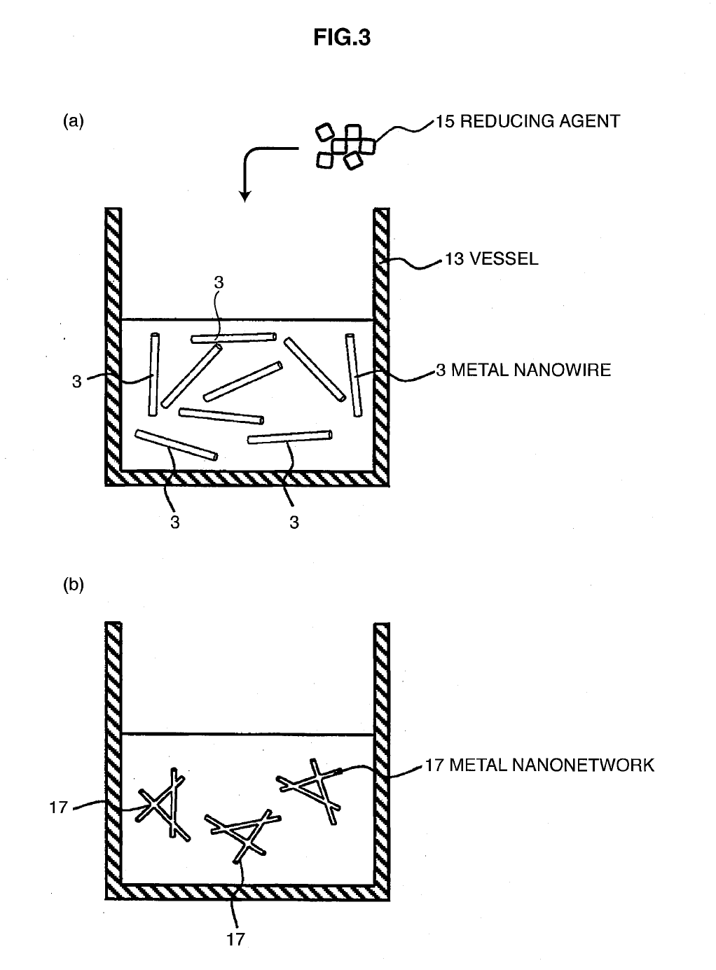

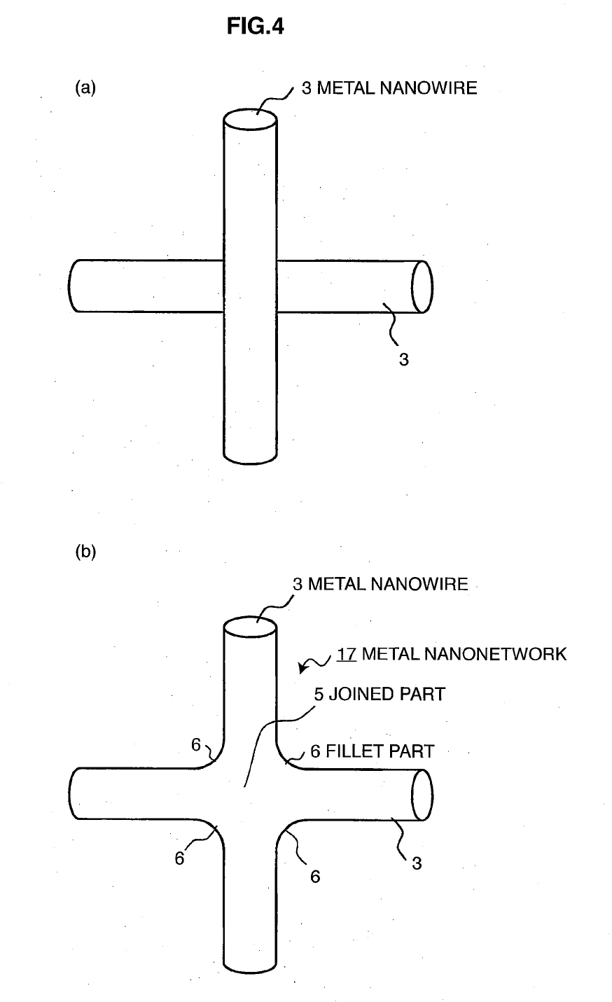

Then, as shown in FIG. 3(a), the metal nanowire 3 having a surface oxide film 7 is added to a liquid and stirred, dispersed by ultrasound etc. and made into a suspension. Further, the metal nanowire 3 is integrated in accordance with the intended morphology, or precipitated in the liquid. For example, as shown in FIG. 4(a) and FIG. 5(a), the metal nanowires 3 are brought to contact with each other.

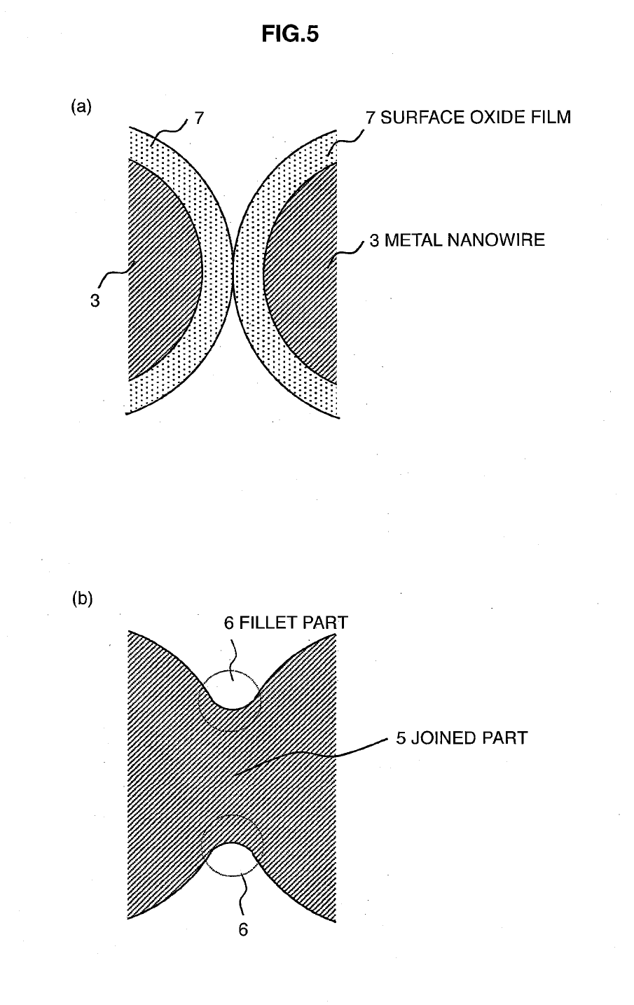

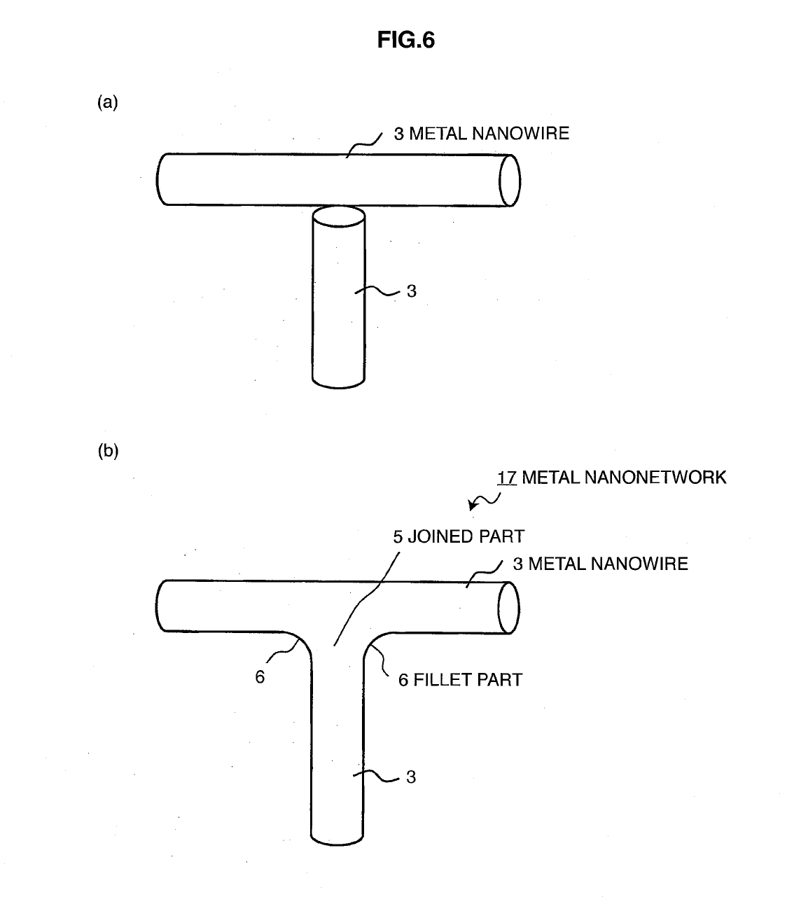

Then, as shown in FIG. 3(a), a reducing agent 15 is added to the liquid, and the oxide film 7 or hydroxide film on the contact point surface between the metal nanowires 3 is reduced. The metal oxide or metal hydroxide is reduced to a metal, and simultaneously, the adjacent metal nanowires 3 integrate and join as shown in FIG. 3(b). At this point, as shown in FIG. 4(a), the metal nanowires join after coming into contact, and the metals that are reduced under a reducing environment transfer so as to decrease the surface area of the joined part 5, and a fillet part 6 is formed on the joined part 5. For example, as shown in FIG. 4(b), FIG. 5(b), cross-shaped or H-shaped fillet parts 6 are formed. Other than the above, as shown in FIG. 6 (a), if the reduction reaction occurs when the end of the metal nanowire 3 is in close proximity to another metal nanowire 3, the joined part 5 may be formed at the middle of the metal nanowire 3, and the fillet part 6 may be formed at the connective part of the trifurcated T-shaped or Y-shaped joined part, as shown in FIG. 6(b). In the present invention, as described above, various embodiments of the connective part can be formed. As a result, a metal nanonetwork 17 comprising various connective parts, as described above, can be formed.

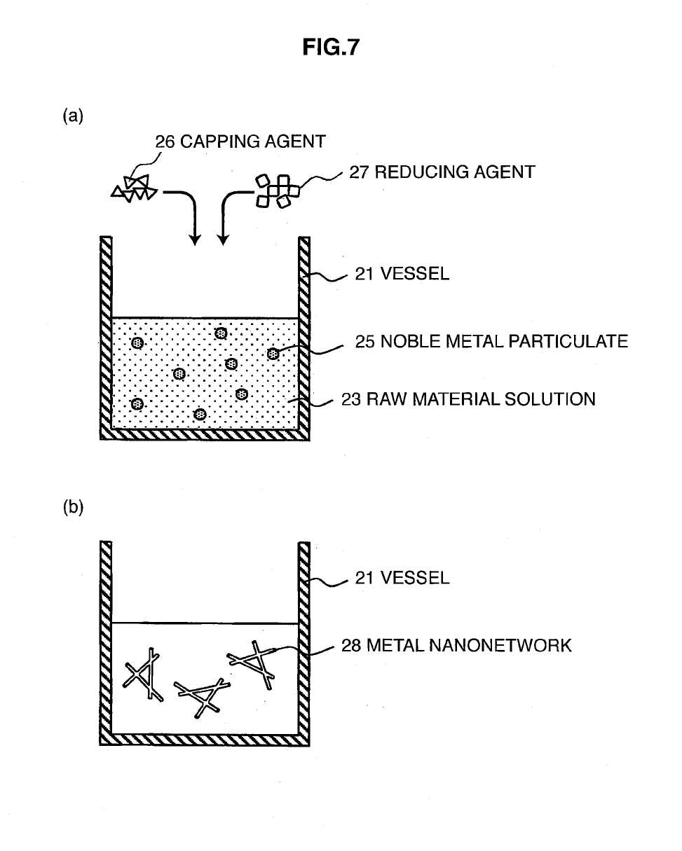

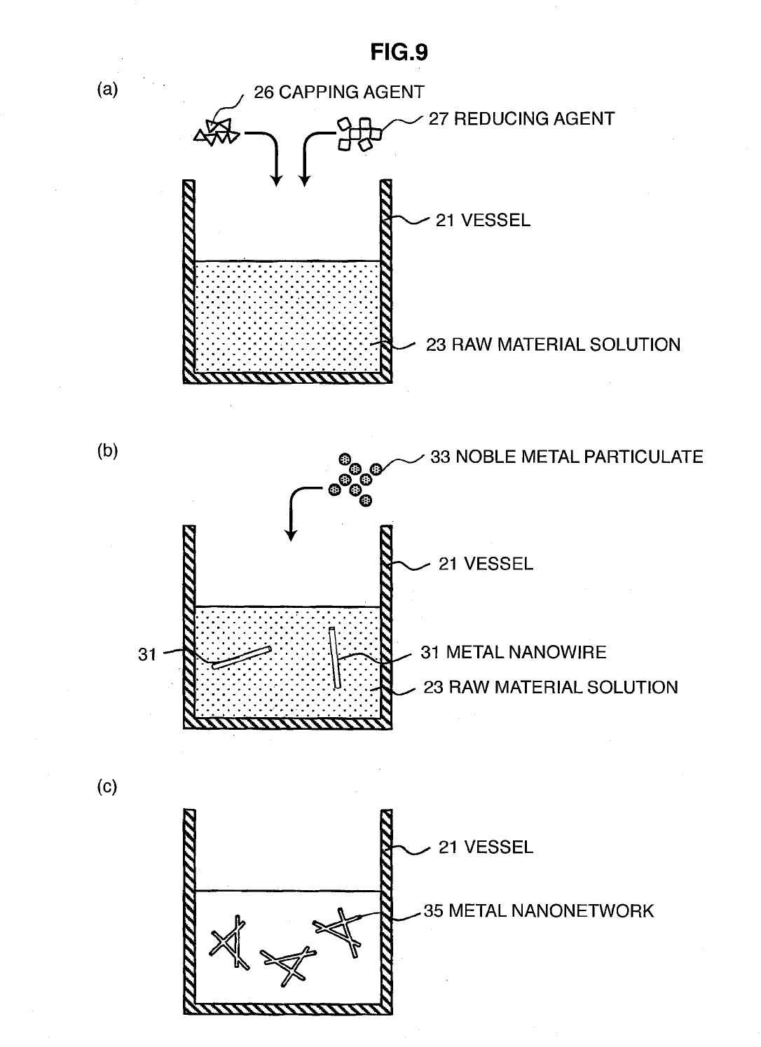

Here, for example, in FIG. 3(b), a metal nanonetwork, formed of three metal nanowires joined at multiple sections, is shown. However, this is merely a schematic illustration, and it should be needless to say that the actual metal nanonetwork comprises a plurality of metal nanowires joined at a plurality of sections. The same may be said for FIG. 7(b), FIG. 9(c).

As the reducing agent 15, metal borohydride compounds, reducing sugars, hydrazine compounds, or polyols, may be used. When polyols are added, heating is preferred to enhance its reducing power. Note that since the reducing potential of the reducing agent in an aqueous solution differ depending on the pH of the solution, an acid or base may be added accordingly, depending on the type of reducing agent used. For example, when a copper nanostructure is reduced using hydrazine, in an environment lower than pH13, it can only be reduced to cuprous oxide. Thus, it is necessary to perform reduction in a strong alkaline solution of pH13 or above. In other reduction methods, heating may be performed under an atmosphere containing hydrogen or formic acid.

In the first method for producing the metal nanonetwork 1, the metal nanonetwork is produced by two separate processes: a process of producing the metal nano structure, and a process of forming the metal nanonetwork. Thus, the metal nanonetwork can be formed in a particular position, by arranging the metal nanostructure in a particular position and then reducing the metal nanostructure. For example, the metal nanonetwork may be formed by applying and drying a pre-networked metal nanostructure that is easily dispersed in a matrix onto a transparent substrate to form a net-like layer, and then reducing the surface of the metal nanostructure. Because the metal nanonetwork can be formed after the metal nanostructure is applied in a state that is easily dispersed in a matrix, the metal nanonetwork can be formed uniformly, even on a substrate with a curved or irregular surface.

Further, as shown in FIG. 4(a), (A) the metal nanonetwork is obtained by the reduction reaction occurring while the surface of the metal nanowire 3 is in contact with another metal nanowire 3; or (B) the metal nanonetwork is formed when the metal nanowires come close enough to contact each other due to the irregular collision motion of the solvent molecules and the solvent motion by heat flow, while the active surface is exposed by the reduction reaction. In the first method for producing the metal nanonetwork, the joined part that becomes the base of the metal nanonetwork is formed by the mechanism of either (A) or (B). As for the distance between the central axes of the metal nanowires, in either of the joining configuration (A) or (B), the distance from the central axis of one metal nanowire to the other is smaller than the sum of the radii of the two. Here, at the exact moment of joining, the distance between the central axes at the joined part of the metal nanowires may be the same as or slightly larger than the sum of the two. However, due to the driving force to decrease the surface energy of the joined part after joining, the metal elements at the joined part transfer, and the central distance between the metal nanowires become smaller than the sum of the radii of the two.

### (Second Method for Producing Metal Nanonetwork)

The second method for producing the metal nanonetwork is as follows. First, to a solution containing at least an ion or complex of one metal element selected from copper, silver, cadmium, iron, zinc, nickel and cobalt as the main metal element that composes the metal nanostructure, a noble metal particulate that contains a metal element that is more noble than said metal element is added.

Here, the phrase “containing at least an ion or complex of one metal element” is not intended to exclude metal ions or complexes other than the metal ion or complex selected from copper, silver, cadmium, iron, zinc, nickel and cobalt, but rather, allows the coexistence of a plurality of metal ions or complexes that were not selected. The range at which a plurality of metal ions or complexes of metals not selected from copper, silver, cadmium, iron, zinc, nickel and cobalt may coexist is in the range at which the lattice constant and crystal structure of the metal forming the metal nanostructure is not largely affected.

Then, a capping agent is added to control the direction of crystal growth, and a reducing agent is further added for the reduction process.

From the above processes, a metal nanonetwork can be produced directly, without undergoing the form of a metal nanowire.

In particular, as shown in FIG. 7(a), a raw material solution 23 that contains an ion or a complex of a given metal element and a capping agent 26 for controlling the crystal growth direction is prepared within a vessel 21. A noble metal particulate 25 without a surface oxide film is added, and a reducing agent 27 is further added.

As the capping agent 26, one that can control the crystal growth direction, so as to produce a metal nanowire, can be used. In particular, as the capping agent 26, a compound that selectively adsorbs to a specific surface of the fine crystal of metal obtained by reduction, and grows the crystal toward a specific direction, is preferable. As the capping agent 26, ethylenediamine, 1,3-propanediamine, 1,2-propanediamine, putrescine, 1,2-diaminocyclohexane, diethylenetriamine, triethylenetetramine, tetraethylenepentamine, pentaethylenehexamine, piperazine, spermine, spermidine, o-phenylenediamine, 3,4-diaminotoluene, 3,4-diaminopyridine can be exemplified.

Further, as the reducing agent 27, reducing agents similar to reducing agent 15 can be used.

As shown in FIG. 8(a), the reducing agent 27 reduces the ion or complex of the metal element in the raw material solution 23 and a metal nanowire 29 of high aspect ratio grows from the noble metal particulate 25a. Subsequently, as shown in FIG. 8(b), the noble metal particulate 25b adsorbs to the surface of the metal nanowire 29a and exposes the active surface of the metal nanowire 29a that is not capped. Then, as shown in FIG. 8(c), the metal nanowire 29b grows once more, with the noble metal particulate 25b acting as the crystal growth nucleus. Further, at this point, the metal depositing in the premises of the noble metal particulate 25b forms the fillet part 6.

Such adsorption of the noble metal particulates on the metal nanowire and the growth of the metal nanowire are repeated, and as shown in FIG. 8(b), FIG. 8(c), the metal nanonetwork 28 is formed.

The metal element that composes the noble metal particulate 25, which does not have a surface oxide film, is a metal element that is more noble in ionization tendency than the metal element of the ion or complex in the raw material solution 23, and preferably, a noble metal element such as gold, silver, platinum, palladium, rhodium, iridium, or ruthenium can be used.

In the second method for producing the metal nanonetwork, when reducing the ion or complex of the metal element, a metal nanonetwork is formed instead of a metal nanowire.

Further, in the metal nanonetwork 28 obtained by the second method for producing the metal nanonetwork, the joined parts comprise a noble metal element derived from the noble metal particulate 25.

Further, since the metal nanowire 29b grows from the noble metal particulate 25b attached to the surface of the metal nanowire 29a in the second method for producing the metal nanonetwork, the central axis of metal nanowire 29a and the central axis of metal nanowire 29b coincide.

### (Third Method for Producing Metal Nanonetwork)

The third method for producing the metal nanonetwork is as follows. First, as shown in FIG. 9(a), to a raw material solution 23 containing at least an ion or complex of one metal element selected from copper, silver, cadmium, iron, zinc, nickel and cobalt as the main metal element that composes the metal nanostructure, a capping agent 26 for controlling the direction of crystal growth is added. Further, a reducing agent 27 is added to perform the reduction process. Subsequently, before the metal nanowire formation reaction is completed, as shown in FIG. 9(b), a noble metal particulate 33 that contains a metal element that is more noble than the metal element included in the nanowire is added. As shown in FIG. 9(c), because the reduction reaction progress under the presence of the noble metal particulate 33, the metal nanowires 31 are connected and networked by the particles that grow with the noble metal particulate 33 acting as the nucleus, to form the metal nanonetwork 35.

More specifically, as shown in FIG. 9(a), a raw material solution 23 that contains an ion or complex of a given metal element is prepared in a vessel 21, and a capping agent 26 for controlling the crystal growth direction and a reducing agent 27 is added.

Thus, as shown in FIG. 10(a), the reducing agent 27 reduces the ion or complex of the metal element in the raw material solution 23, and metal nanowires 31a and 31b of high aspect ratio are formed. Subsequently, when the noble metal particulate 33 is added during the process of the metal nanowire formation reaction, that is, before the metal nanowire formation reaction is completed, as shown in FIG. 10(b), the noble metal particulate 33 adsorbs on the surface of the metal nanowire 31a. Further, the surface of the metal nanowire 31b also adheres to the noble metal particulate 33.

By adhering to the metal nanowire 31a, the noble metal particulate 33 exposes the active surface that is not capped, and as shown in FIG. 10(c), metal deposits around the noble metal particulate 33. The metal nanowires 31a and 31b are joined, the fillet part 6 is formed, and the metal nanonetwork 35 is formed.

Alternatively, in the third production method, as in the second production method, the metal nanowire may grow from the noble metal particulate 33 adhered to the surface of the metal nanowire 31a.

Such adsorption of the noble metal particulate on the metal nanowire and the formation of the joined part are repeated, and as shown in FIG. 9(c), FIG. 10(c), the metal nanonetwork 35 is formed.

The metal element that composes the noble metal particulate 33 is a metal element that is more noble in ionization tendency than the metal element of the ion or complex in the raw material solution 23, and is preferably a noble metal element such as gold, silver, platinum, palladium, rhodium, iridium, or ruthenium.

In the third method for producing the metal nanonetwork, by reducing an ion or a complex of the metal element in the presence of metal nanowire 31a, metal nanowire 31b, and noble metal particulate 33, the metal nanowires are joined and a metal nanonetwork is formed.

Further, the metal nanonetwork 35 obtained comprises a noble metal element derived from the noble metal particulate 33 in the joined part.

### (Use of the Metal Nanonetwork)

The metal nanonetwork 1 can be used as fillers for conductive substrates or conductive adhesives, by producing the metal nanonetwork 1 on a substrate and removing the solvent, or by applying the metal nanonetwork 1 on a substrate or adding in to a resin.

If the film or resin is a transparent substrate that is visible-light transmissive, a conductive substrate that has both conductivity and transparency can be made. Further, a film on which the metal nanonetwork 1 and a polygonal window are formed can be used as an electromagnetic wave shielding sheet.

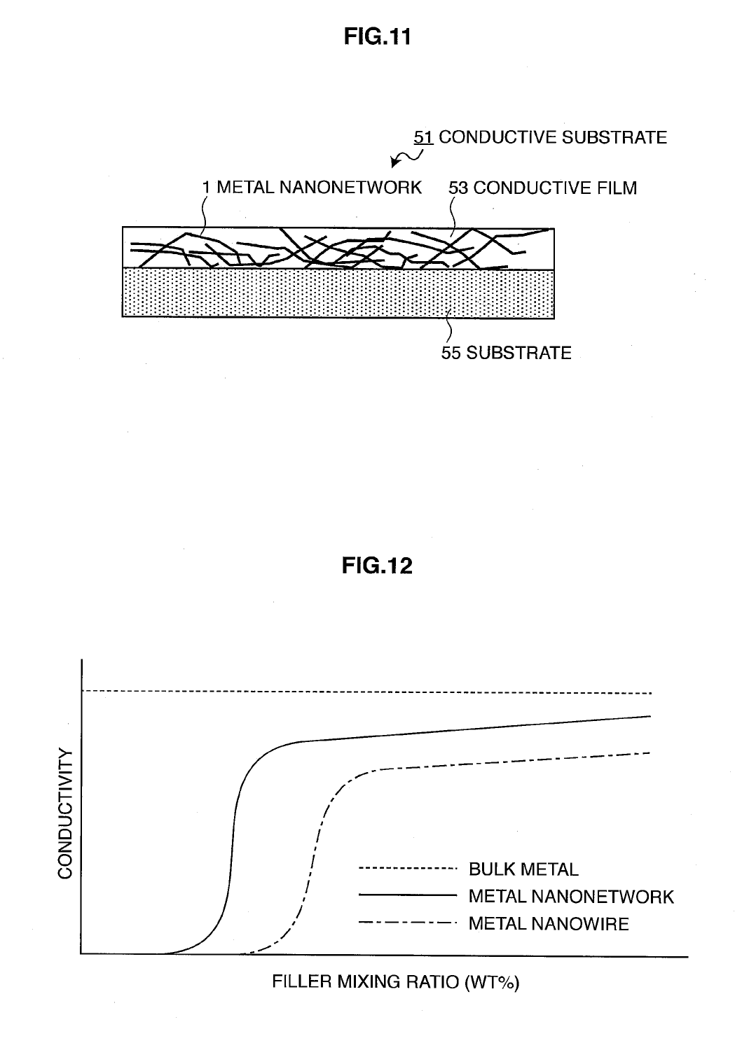

FIG. 11 is a partial cross-sectional view of a conductive substrate 51 that uses the metal nanonetwork 1. The conductive substrate 51 is formed by applying an ink, which contains the metal nanonetwork 1 and a matrix resin, on a substrate 55 of resin, ceramic, or metal, and drying to form a conductive film 53. Further, a protective layer of resin etc. may be formed on the conductive layer, after applying a liquid with the metal nanonetwork 1 dispersed thereto, and drying to form a conductive layer consisting of the metal nanonetwork 1. Further, by using a film in which the metal nanonetwork 1 is dispersed in a transparent matrix resin as the conductive film, and a transparent substrate such as glass and polyester film as the substrate 55, the conductive substrate 51 becomes transparent.

In the conductive substrate 51 that utilizes the metal nanonetwork 1, because high conductivity can be obtained with a small amount of application, the amount of conductive fillers added can be reduced, compared to conductive substrates that utilize metal nanowires, and further, excellent transparency is obtained.

The conductive substrate 51 can be used as displays, touch panels, mobile phones, electronic papers, various solar batteries, and various electrodes for electroluminescence dimmer elements.

Further, by supporting substances that alloy with lithium, such as silicon and tin, on the metal nanonetwork 1, it can be used as an anode material for lithium ion secondary battery.

The anode material is prepared by forming an active material layer of silicon or tin etc. on the surface of the metal nanonetwork 1 by spattering or chemical vapor deposition (CVD) etc. By applying the anode material on a current collector of copper foil etc., along with a conductive assistant such as carbon black, an anode for lithium ion secondary battery can be prepared.

In the anode material that utilizes the metal nanonetwork 1, because the metal nanostructures are joined at the contact point, favorable paths for electric conduction are created, and enhancement of energy density and enhancement of charge/discharge speed becomes possible. Further, because the metal nanostructures are tightly bonded at the contact points in the metal nanonetwork 1, the anode material does not deteriorate even when charge/discharge is repeated.

Further, the metal nanonetwork 1 can be used as a catalyst or electrode material for a fuel cell. For example, when the metal nanonetwork 1 is of a copper-type, the metal nanonetwork 1 itself can be used as a carbon monoxide modification catalyst for a fuel cell. In the metal nanonetwork 1, because the metal nanostructures are joined to each other at the contact point and are tightly bound, the catalyst does not deteriorate even when force is applied from outside. Thus, it becomes a catalyst that can be used for a long period of time. Further, when the metal nanonetwork 1 is used as a support for the catalyst, and a certain catalyst is supported on its surface, because the metal nanonetwork 1 is strong, it can be used for a long period of time, and becomes a catalyst that shows superior charge transfer properties.

### (Effect of the Metal Nanonetwork)

Because the metal nanonetwork of the present embodiment is formed by the joining of the metal nanostructures by metallic bond, without the intervention of oxides or hydroxides at the contact point, compared to a simple aggregate of metal nanostructures, there is little resistance at the contact points. Thus, when dispersed in a matrix, the conductivity becomes higher compared to the case where a simple aggregate of the metal nanostructures is added.

Because the metal nanonetwork of the present embodiment has a network structure wherein metal nanostructures are joined at contact points, compared to the case where an aggregate of a metal nanostructure is used as the metal filler, the minimum amount of metal filler necessary to form a conductive path consisting of the conductive metal in a resin matrix (percolation threshold) can be reduced.

To summarize the above-described effects, the relationship between the mixing ratio of the metal nanonetwork or metal nanowire when mixed in resin as conductive fillers and the conductivity is as shown in the schematic diagram of FIG. 12. That is, when the metal nanonetwork of the present embodiment is used, compared to when a simple metal nanowire is used, the percolation threshold, at which the conductivity shows a sudden rise, is obtained with a small amount of filler mixing ratio. Further, due to the effect of the contact resistance being reduced, the conductivity tends to be higher, even at the same filler mixing ratio.

Furthermore, in the metal nanonetwork of the present embodiment, because the central axis of one metal nanostructure and the central axis of the other metal nanostructure coincide at the joined part, the metal nanostructures are tightly bound together, and conduction can be maintained even when force is added from outside.

Further, because the metal nanonetwork of the present embodiment comprises a fillet part at the joined part, the metal nanostructures are tightly joined, and the mechanical strength of the metal nanonetwork 1 is enhanced.

Hereinafter, the present invention will be described in detail with reference to the following Examples.

### EXAMPLE 1

### (Preparation of Copper Nanowire)

To a 100 mL four-necked flask, 40 mL of a 15 mol/L sodium hydroxide aqueous solution, 0.30 mL of ethylenediamine, and 2.0 mL of a 0.1 mol/L cupric nitrate aqueous solution were added and stirred using a stirrer.

Then, inert gas substitution of the vessel and the solution was performed by nitrogen bubbling for 90 minutes. More specifically, the oxygen gas content was set to less than 1 ppm.

A heater was set to 60° C. and heated. Bubbling was terminated when the temperature rose.

To the above flask, 50 μL of hydrazine was injected using a syringe. After maintaining under nitrogen flow and stirring for 10 minutes, the heater power was turned off. The flask was cooled to about 30° C. in a water bath.

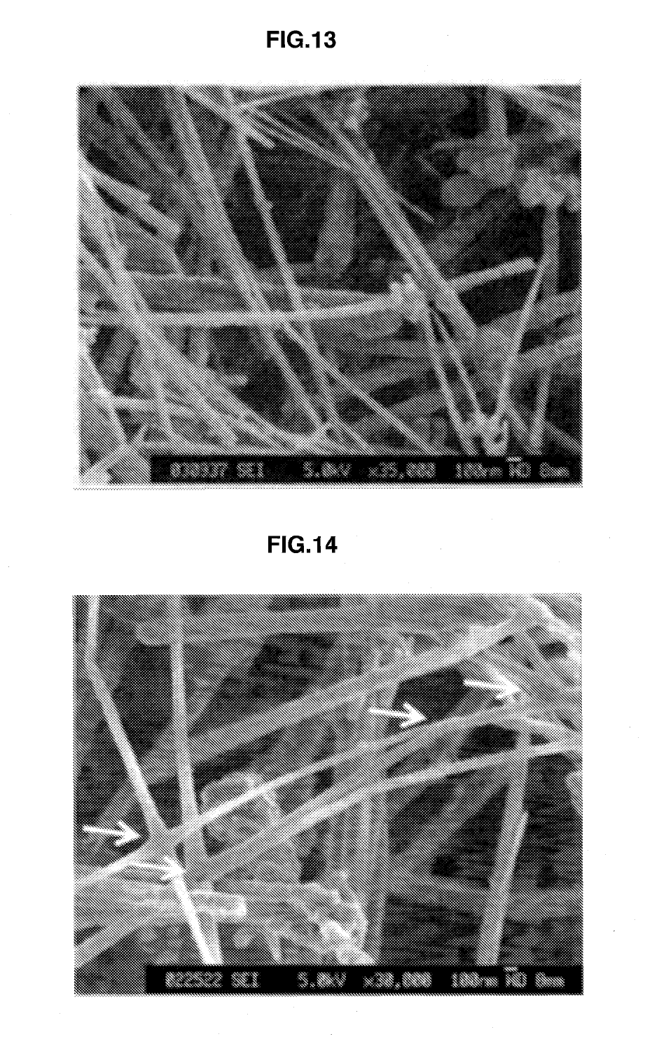

After the product was separated by centrifugation and washed with distilled water, copper nanowire was obtained. FIG. 13 is a scanning electron micrograph of the copper nanowire. It can be seen that linear copper nanowires of about 60 to 200 nm with smooth surfaces were obtained.

### (Preparation of Copper Nanonetwork)

The copper nanowire was added to distilled water that had not been deoxidized to form an oxide film, and was precipitated by a centrifuge.

Several drops of a mixture of sodium hydroxide and hydrazine were added to the above state to reduce the oxide film.

Subsequently, the product was separated by centrifugation and washed to obtain the copper nanonetwork.

FIG. 14 is a scanning electron micrograph of the copper nanonetwork. It can be seen that linear copper nanowires of about 60 to 200 nm with smooth surfaces are joined at the sections indicated by the arrows to form a network structure. Further, in the sections indicated by the arrows, it can be seen that the joined parts are thicker than the copper nanowire, and the formation of fillet parts in the joined parts can be observed. Further, in the sections indicated by the arrows, the central axis of the copper nanowire almost coincides with the central axis of the other copper nanowire joined thereto, and the distance between the central axes is smaller than the sum of the radii of the copper nanowires.

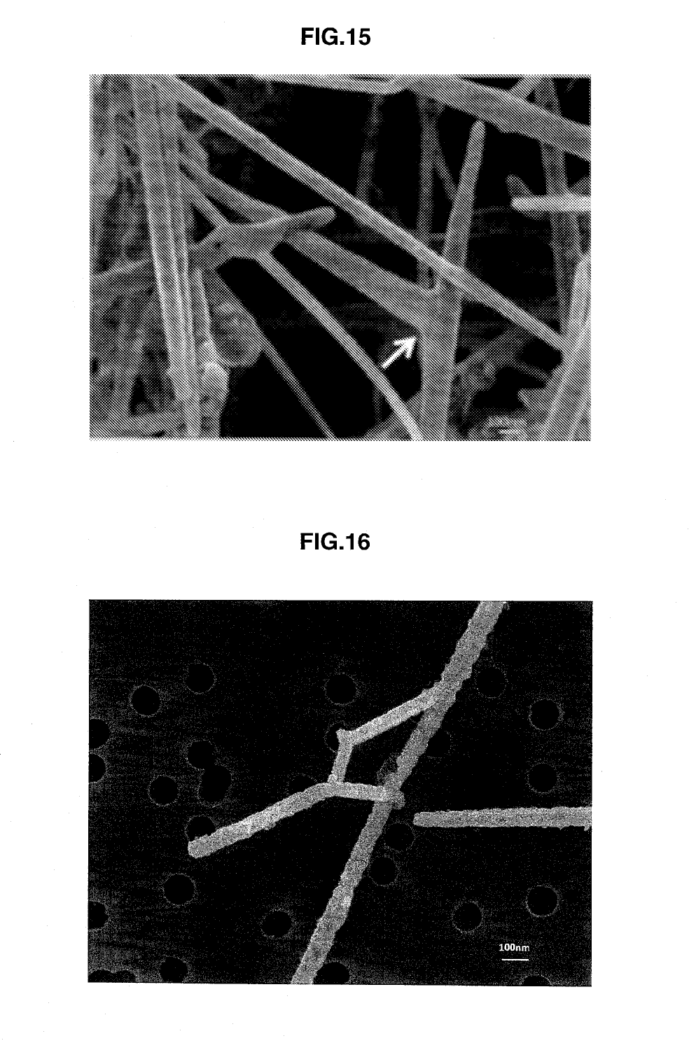

FIG. 15 is a scanning electron micrograph of the copper nanonetwork. It can be seen that linear copper nanowires of about 50 to 150 nm with smooth surfaces are joined with one another, and that a network structure is formed. Further, in the section indicated by the arrow on the right, a trifurcated branching structure is observed. Further, at the section indicated by the arrow, the central axis of the copper nanowire almost coincides with the central axis of the other copper nanowire joined thereto, and the distance between the central axes is smaller than the sum of the radii of the copper nanowires. Further, formation of a fillet part at the joined part of the copper nanowires can be seen.

FIG. 16 is a scanning electron micrograph of the copper nanonetwork. A state in which copper nanowires with a thickness of about 60 nm are about to join can be observed. This micrograph is thought to be of the initial stage of the joining of the copper nanowires, and a fillet part is not particularly formed on the joined part.

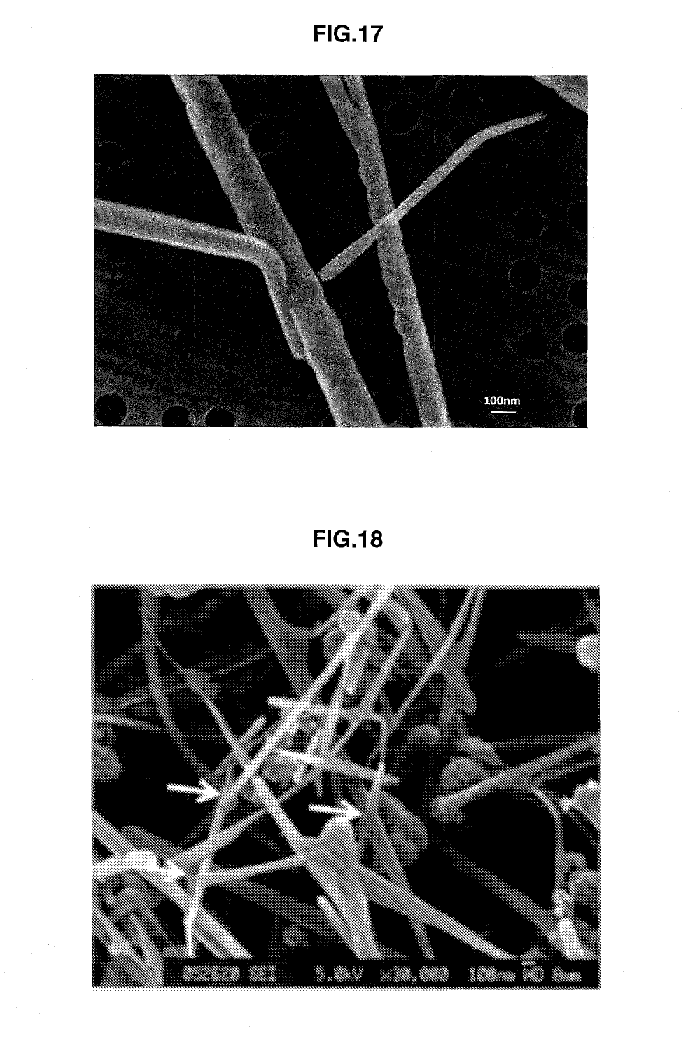

FIG. 17 is a scanning electron micrograph of the copper nanonetwork. A state in which copper nanowires with a thickness of about 40 to 150 nm are about to join can be observed. This micrograph is also thought to be of the initial stage of the joining of the copper nanowires, and a fillet part is not particularly formed on the joined part.

### EXAMPLE 2

To a 100 mL four-necked flask, 40 mL of a 15 mol/L sodium hydroxide aqueous solution, 0.30 mL of ethylenediamine, and 2.0 mL of a 0.1 mol/L cupric nitrate aqueous solution were added and stirred using a stirrer.

Then, as in Example 1, after nitrogen bubbling and heating of the solution, 1 mL of a gold colloidal dispersion containing 1 wt % of gold particulates with an average particle diameter of 5 nm was added and stirred.

As described in Example 1, in the subsequent operations, hydrazine injection, maintaining of the temperature, cooling, and centrifugation was performed, to obtain the copper nanonetwork.

FIG. 18 is a scanning electron micrograph of the copper nanonetwork. It can be seen that a linear copper nanowire of about 30 to 200 nm with smooth surfaces are joined at sections such as those marked by the arrows, to form a network structure. Further, at the positions marked by the arrows, the joined parts are thicker than the copper nanowire, indicating that fillet parts were formed at the joined parts. Furthermore, at sections marked by the arrows, the central axis of the copper nanowire almost coincides with the central axis of the other copper nanowire joined thereto, and the distance between the central axes is smaller than the sum of the radii of both copper nanowires.

Although preferred embodiments of the present invention have been described above with reference to the accompanying figures, the present invention is not limited to such examples. It should be obvious to those in the field that examples of various changes and modifications are conceivable within the realm of the technical idea disclosed in the present specification, and it should be understood that such examples are justifiably included in the technical scope of the present invention.

### DESCRIPTION OF NOTATION

1 . . . metal nanonetwork
3, 3a, 3b . . . metal nanowire
4a, 4b . . . central axis
5 . . . joined part
6 . . . fillet part
7 . . . surface oxide film
11 . . . metal nanodendrite
13 . . . vessel
15 . . . reducing agent
17 . . . metal nanonetwork
21 . . . vessel
23 . . . raw material solution
25, 25a, 25b . . . noble metal particulate
26 . . . capping agent
27 . . . reducing agent
28 . . . metal nanonetwork
29a, 29b . . . metal nanowire
31, 31a, 31b . . . metal nanowire
33 . . . noble metal particulate
35 . . . metal nanonetwork
51 . . . conductive substrate
53 . . . conductive film
55 . . . substrate

1. A metal nanonetwork, which comprises metal nanostructures that are joined by metallic bond, wherein the joined part between the metal nanostructures comprise a fillet part, wherein at least part of the metal nanostructures penetrate each other, and in the joined part between the metal nanostructures, the distance between the central axis of one metal nanostructure and the central axis of another metal nanostructure is smaller than the sum of the radii of the metal nanostructures, and
the metal nanostructures are a metal nanowires, and formed of single crystal or multiple twinning, wherein the crystal orientation in the axial direction of the metal nanowire is constant, and an oxide does not intervene in the joined part between the metal nanostructures.

2. The metal nanonetwork of claim 1, which comprises a fillet part, wherein at least part of the metal nanostructures penetrate each other, at the joined part between the metal nanostructures, and the thickness of the fillet part in the metal nanostructure is thicker than the thickness of the metal nanostructure, and the cross-sectional area of the joined part between the metal nanostructures is larger than the cross-sectional area of the metal nanostructure.

3. The metal nanonetwork of claim 1, wherein a three-dimensional network is formed.

4. The metal nanonetwork of claim 1, which comprises a trifurcated branching structure.

5. (canceled)

6. The metal nanonetwork of claim 1, wherein the metal nanostructure comprises one metal selected from copper, silver, cadmium, iron, zinc, nickel and cobalt, as a main metal element that forms the metal nanostructure.

7. (canceled)

8. The metal nanonetwork of claim 1, which comprises a metal element that is more noble than the metal element composing the metal nanostructure, in the joined part between the metal nanostructures.

9. The metal nanonetwork of claim 8, which comprises one metal element selected from copper, silver, cadmium, iron, zinc, nickel and cobalt as a main metal element composing the metal nanostructure, and the metal element that is more noble than the metal element composing the metal nanostructure is at least one metal element selected from gold, silver, platinum, palladium, rhodium, iridium, and ruthenium.

10. The metal nanonetwork of claim 8, wherein the metal nanostructure is a single-crystal copper nanowire and the joined part between the metal nanostructures is composed of gold or an alloy of gold and copper.

11. A method for producing a metal nanonetwork, which comprises a process of forming an oxide film on the outer-most surface of a metal nanostructure, and a process of reducing the oxide film at the joined parts between a plurality of metal nanostructures to thereby join the metal nanostructures.

12. The method for producing a metal nanonetwork of claim 11, wherein the reducing of the oxide film is performed in a liquid containing a reducing agent.

13. The method for producing a metal nanonetwork of claim 12, wherein the reducing agent is one of or a mixture of metal borohydride compounds, reducing sugars, hydrazine compounds, and polyols.

14. The method for producing a metal nanonetwork of claim 11, wherein the metal nanostructure is a copper nanowire or a copper nanodendrite.

15. A method for producing a metal nanonetwork, wherein
to a solution containing an ion or a complex of at least one metal element selected from copper, silver, cadmium, iron, zinc, nickel, and cobalt, as a main metal element that composes the metal nanostructure,
a noble metal particulate, which contains a metal element that is more noble than the metal element in the solution, is added, and further,
a capping agent, which selectively adsorbs to a specific surface of the metal element crystal to thereby grow the crystal in a specific direction, and a reducing agent are added.

16. A method for producing a metal nanonetwork, wherein
to a solution containing an ion or a complex of at least one metal element selected from copper, silver, cadmium, iron, zinc, nickel, and cobalt, as a main metal element that composes the metal nanostructure,
a capping agent, which selectively adsorbs to a specific surface of the metal element crystal to thereby grow the crystal in a specific direction, and a reducing agent are added to thereby form a metal nanowire, and
during the metal nanowire formation reaction, a noble metal particulate that contains a metal element that is more noble than the metal element in the solution is added, to thereby join the metal nanowires to form a metal nanonetwork.

17. The method for producing a metal nanonetwork of claim 15, wherein the noble metal particulate contains at least one metal element selected from gold, silver, platinum, palladium, rhodium, iridium, and ruthenium.

18. The method for producing a metal nanonetwork of claim 15, wherein the metal element is copper and the metal element that is more noble is gold.

19. The method for producing a metal nanonetwork of claim 15, wherein the capping agent is ammonia or an amine.

20. The method for producing a metal nanonetwork of claim 15, wherein the reducing agent is hydrazine or a derivative thereof

21. A conductive film, which comprises the metal nanonetwork of claim 8 embedded within a matrix resin.

22. A conductive substrate, which comprises the conductive film of claim 21 formed on a substrate consisting of a resin, ceramic, or metal.
